(19) United States
(12) Patent Application Publication
(10) Pub. No.: US 2022/0084930 A1
(43) Pub. Date: Mar. 17, 2022

(54) ELECTRONIC COMPONENT MOUNTING BASE AND ELECTRONIC DEVICE

(71) Applicant: KYOCERA Corporation, Kyoto-shi, Kyoto (JP)

(72) Inventors: Narutoshi OGAWA, Kirishima-shi (JP); Mitsuharu SAKAI, Kirishima-shi (JP); Hikaru KITAHARA, Kirishima-shi (JP)

(73) Assignee: KYOCERA Corporation, Kyoto-shi, Kyoto (JP)

(21) Appl. No.: 17/425,350

(22) PCT Filed: Jan. 29, 2020
(86) PCT No.: PCT/JP2020/003192

§ 371 Date: Jul. 23, 2021

(30) Foreign Application Priority Data
Jan. 30, 2019 (JP) 2019-014098

(51) Int. Cl. H01L 23/498; H01L 21/48

(52) U.S. Cl. CPC H01L 23/49838; H01L 23/49822; H01L 21/4857

(57) ABSTRACT

An electronic component mounting base includes a base, a first, second and third conductor layers, and first and second via conductors. The base includes first and second insulating layers. The first insulating layer has a first surface and a second surface opposite to the first surface. The second insulating layer has a third surface facing overlapping the second surface, and a fourth surface opposite the third surface. The first conductor layer includes a first electrode portion positioned on the first surface. The second conductor layer is positioned between the second and third surfaces. The third conductor layer includes a second electrode portion positioned on the fourth surface. The first via conductor extends penetrating from the first to the second surfaces, and connects the first conductor and second conductor layers. The second via conductor extends penetrating from the third to the fourth surfaces, and connects the second and third conductor layers.

### TECHNICAL FIELD

The present disclosure relates to an electronic component mounting base and an electronic device.

### BACKGROUND ART

A known electronic component mounting base is provided with a wiring base including an insulating layer. There is disclosed an electronic device in which an electronic component is mounted on such an electronic component mounting base (see Patent Document 1).

### CITATION LIST

### Patent Literature

Patent Document 1: JP 2017-157693 A

### SUMMARY

An electronic component mounting base according to an embodiment of the present disclosure includes a base, a first conductor layer, a second conductor layer, a third conductor layer, a first via conductor, and a second via conductor. The base includes a first insulating layer and a second insulating layer. The first insulating layer has a first surface and a second surface positioned opposite to the first surface. The second insulating layer has a third surface facing and overlapping the second surface, and a fourth surface positioned opposite to the third surface. The first conductor layer includes a first electrode portion and is positioned on the first surface. The second conductor layer is positioned between the second surface and the third surface. The third conductor layer includes a second electrode portion and is positioned on the fourth surface. The first via conductor extends penetrating from the first surface to the second surface, and connects the first conductor layer and the second conductor layer. The second via conductor extends penetrating from the third surface to the fourth surface, and connects the second conductor layer and the third conductor layer. A distance D1 between the first electrode portion and the first via conductor is longer than a distance D2 between the first electrode portion and the second via conductor in a plane perspective toward the first surface. A distance D3 between the second electrode portion and the second via conductor is longer than a distance D4 between the second electrode portion and the first via conductor in the plane perspective toward the first surface.

An electronic device according to an embodiment of the present disclosure includes the electronic component mounting base and an electronic component connected to the electronic component mounting base.

### BRIEF DESCRIPTION OF DRAWINGS

FIG. 1 is a perspective view of an electronic component mounting base according to an embodiment of the present disclosure.

FIG. 2 is a plan view of an electronic component mounting base according to an embodiment of the present disclosure.

FIG. 3 is a cross-sectional view taken along a line X-X in FIG. 2 of the present disclosure.

FIG. 4 is a cross-sectional view taken along the line X-X in FIG. 2 of the present disclosure.

FIG. 5 is a cross-sectional view of an electronic device according to an embodiment of the present disclosure.

### DESCRIPTION OF EMBODIMENTS

### Configuration of Electronic Component Mounting Base 1

Several exemplary embodiments of the present disclosure will be described with reference to the drawings. In the following description, a configuration in which an electronic component 101 is mounted on an electronic component mounting base 1 is taken as an electronic device 100. In the present specification, the electronic component mounting base 1 and the electronic device 100 may be described based on an orthogonal coordinate system of xyz for convenience. In the present specification, description may be given in which the positive side of the z direction is taken as an upper side and the negative side of the z direction is taken as a lower side, and a surface on the upper side is taken as an upper surface and a surface on the lower side is taken as a lower surface.

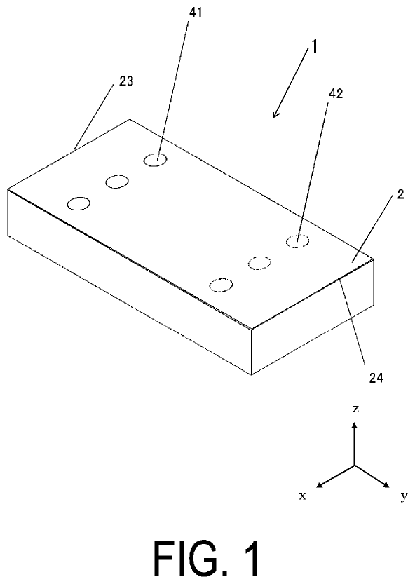

As illustrated in FIG. 1, the electronic component mounting base 1 includes a base 2. The base 2 may include a flat plate portion and a frame portion positioned on the flat plate portion, or may include only the flat plate portion. In the drawings, an example in which the base 2 includes only the flat plate portion is disclosed.

As a material for the base 2, an electrically-insulating ceramic or a resin may be used, for example. As the electrically-insulating ceramic, for example, an aluminum oxide-based sintered body, a mullite-based sintered body, a silicon carbide-based sintered body, an aluminum nitride-based sintered body, a silicon nitride-based sintered body, or a glass ceramic sintered body may be used. As the resin, a thermoplastic resin, an epoxy resin, a polyimide resin, an acrylic resin, a phenol resin, or a fluorine-based resin may be used. As the fluorine-based resin, a polyester resin or an ethylene tetrafluoride resin, for example, may be used. The base 2 may be formed by layering these materials, and may be referred to herein as an insulating layer when the base 2 is formed by the layering.

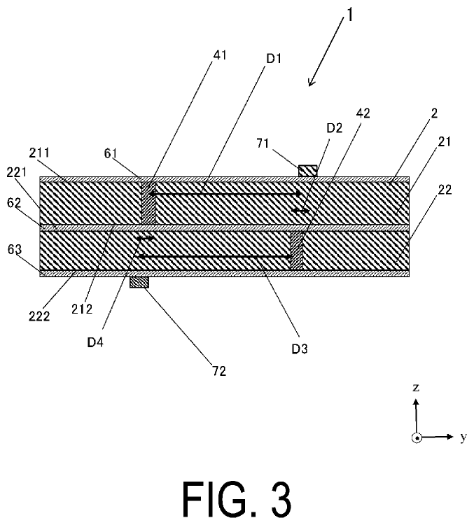

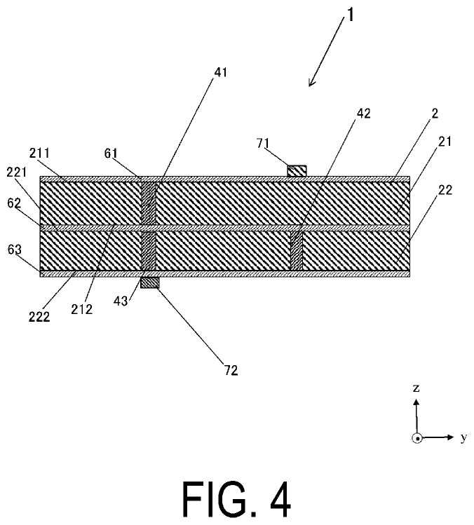

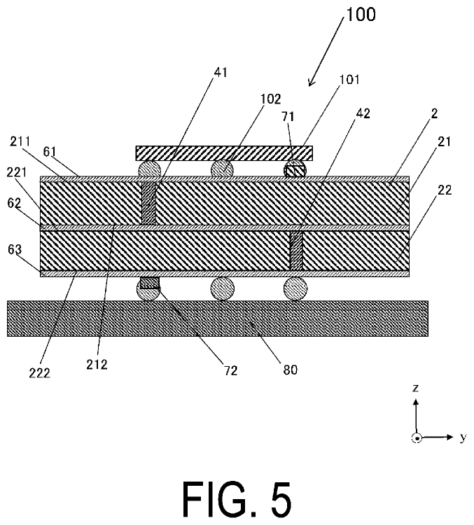

The base 2 may be formed of two insulating layers as illustrated in FIGS. 3, 4 and 5, or may be formed of three or more insulating layers. The base 2 may not take a layered form, and this makes it possible to reduce the thickness of the electronic component mounting base 1. When the base 2 is formed of three or more insulating layers, the rigidity of the electronic component mounting base 1 may be enhanced. In the present specification, a case will be described in which the base 2 is formed of two insulating layers including a first insulating layer 21 and a second insulating layer 22.

The first insulating layer 21 has a first surface 211 and a second surface 212 positioned opposite to the first surface 211. The first surface 211 may be described as an upper surface of the first insulating layer 21 and the second surface 212 may be described as a lower surface of the second insulating layer 22. The second insulating layer 22 has a third surface 221 facing and overlapping the second surface 212, and a fourth surface 222 positioned opposite to the third surface 221. The third surface 221 may be described as an upper surface of a third insulating layer 23 and the fourth surface 222 may be described as a lower surface of the second insulating layer 22.

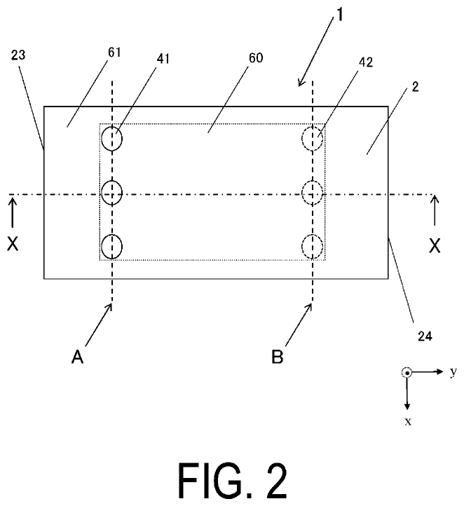

As illustrated in FIG. 2, the base 2 may have a rectangular shape in a plan view toward the first surface 211. When the base 2 has a rectangular shape, the base 2 may be square or rectangular. When the base 2 has a rectangular shape, the base 2 may have a first side 23 and a second side 24 facing the first side. The size of one side of the base 2 may be from 0.3 mm to 10 cm, and the thickness of one side of the base 2 may be equal to or greater than 0.2 mm.

The frame portion and the flat plate portion may be formed of the same material or may contain different materials. When the frame portion and the flat plate portion are formed of the same material, the frame portion and the flat plate portion can be fired at the same temperature. Further, since physical properties such as coefficient of thermal expansion and thermal conductivity are the same, the electronic component mounting base 1 is produced in such a manner that little cracking occurs due to heat generated by the electronic component 101 mounted on the electronic component mounting base 1.

In the present specification, both a first electrode portion 71 and a second electrode portion 72 may be described as electrode pads for convenience, and in this case, no reference sign is assigned to the electrode pads. Further, in the present specification, all of a first conductor layer 61, a second conductor layer 62, and a third conductor layer 63 may be described as wiring conductors for convenience, and in this case, no reference sign is assigned to the wiring conductors. Furthermore, in the present specification, both a first via conductor 41 and a second via conductor 42 may be described as via conductors for convenience, and in this case, no reference sign is assigned to the via conductors.

The first conductor layer 61 is positioned on an upper surface of the first insulating layer 21. The second conductor layer 62 is positioned on a lower surface of the first insulating layer 21 and on an upper surface of the second insulating layer 22. In other words, the second conductor layer 62 is positioned between the first insulating layer 21 and the second insulating layer 22. The third conductor layer 63 is positioned on a lower surface of the second conductor layer 62 and the second insulating layer 22. The third conductor layer 63 may be positioned on a lower surface of the base 2. In a case where there is another insulating layer on the lower surface of the third insulating layer 23, the third conductor layer 63 may be positioned between the other insulating layer and the second insulating layer 22.

The first conductor layer 61 includes the first electrode portion 71 to be electrically connected with a mounting region 60. The third conductor layer 63 includes the second electrode portion 72 to be electrically connected to the outside. When the lower surface of the third insulating layer 23 is the lower surface of the base 2, the outside refers to a mounting substrate 80, on which the base 2 is mounted, or the like. In the case where there is another insulating layer on the lower surface of the second insulating layer 22, the outside refers to wiring positioned on the other insulating layer. When the third conductor layer 63 is positioned on the lower surface of the base 2, the third conductor layer 63 may be used to connect with an external base or the like. In the present specification, among the surfaces of the electronic component mounting base 1, a region where the electronic component 101 is mounted is referred to as the mounting region 60.

When a current flows through each of the first conductor layer 61, the second conductor layer 62, and the third conductor layer 63, mutual inductance increases in a case where the directions of the currents flowing through the first conductor layer 61 and the second conductor layer 62 are the same, and the directions of the currents flowing through the second conductor layer 62 and the third conductor layer 63 are the same. The electronic component mounting base 1 with increased mutual inductance exhibits poor electrical characteristics. The mutual inductance can be reduced by adjusting the positions of the via conductors or the like to be described below so as to adjust the path in which the current flows.

The first via conductor 41 extends penetrating through the first insulating layer 21 from the upper surface to the lower surface, and connects the first conductor layer 61 and the second conductor layer 62. In other words, the first via conductor 41 extends penetrating from the first surface 211 to the second surface 212, and connects the first conductor layer 61 and the second conductor layer 62. The second via conductor 42 extends penetrating through the second insulating layer 22 from the upper surface to the lower surface, and connects to the second conductor layer 62 and the third conductor layer 63. In other words, the second via conductor 42 extends penetrating from the third surface 221 to the fourth surface 222, and connects the second conductor layer 62 and the third conductor layer 63. By disposing the via conductors in the manner to be described below, the direction of the current from the first electrode portion 71 to the first via conductor 41 in the first conductor layer 61 and the direction of the current from the first via conductor 41 to the second via conductor 42 in the second conductor layer 62 are made opposite to each other, so that mutual inductance is reduced.

In a plane perspective toward the first surface 211, the first via conductor 41 is positioned in such a manner that the first electrode portion 71 is further separated therefrom than the second electrode portion 72. In addition, the second via conductor 42 is positioned in such a manner that the second electrode portion 72 is further separated therefrom than the first electrode portion 71. In other words, a distance D1 between the first electrode portion 71 and the first via conductor 41 is longer than a distance D2 between the first electrode portion 71 and the second via conductor 42 in the plane perspective toward the first surface 211. A distance D3 between the second electrode portion 72 and the second via conductor 42 is longer than a distance D4 between the second electrode portion 72 and the first via conductor 41. Since D1 is longer than D2 and D3 is longer than D4, the path of the current can be adjusted in such a manner that the current flows through the mounting region 60, the first conductor layer 61, the first electrode portion 71, the first via conductor 41, the second conductor layer 62, the second via conductor 42, the second electrode portion 72, and the third conductor layer 63 in that order. By adjusting the path of the current in this way, the electronic component mounting base 1 with reduced mutual inductance exhibits favorable electrical characteristics. In the present specification, the plane perspective is a see-through view toward an optional plane, and may be used when describing the positional relationship between objects having different depths.

In a plane perspective toward the first surface 211, the first electrode portion 71, the first via conductor 41, the second electrode portion 72, and the second via conductor 42 may be disposed on a virtual straight line X illustrated in FIG. 2, whereby the path along which the current flows may be more easily adjusted. As a result, the mutual inductance of the electronic component mounting base 1 is further reduced, and the electrical characteristics of the electronic component mounting base 1 are favorable. The virtual straight line X refers to a virtual straight line passing through all of the first electrode portion 71, the first via conductor 41, the second electrode portion 72, and the second via conductor 42. In FIG. 2, the virtual straight line X is indicated by a dashed line and passes through the center of each of the first via conductor 41 and the second via conductor 42. In FIG. 2, the second via conductor 42 positioned in a plane perspective is also described with a dashed line.

FIGS. 3, 4, and 5 are cross-sectional views taken along the virtual straight line X. As illustrated in FIGS. 3 to 5, when the base 2 has a rectangular shape, the first electrode portion 71 and the second electrode portion 72 may be disposed on a diagonal line of the base 2 in a cross-sectional view intersecting with the first surface 211 and including the first electrode portion 71, the first via conductor 41, the second electrode portion 72, and the second via conductor 42. This makes it easier to control the path of the current. The mutual inductance of the electronic component mounting base 1, in which the current path is more easily controlled as described above, is further reduced, and the electrical characteristics of the electronic component mounting base 1 are favorable.

The first electrode portion 71 and the second electrode portion 72 may protrude from the conductor layers as illustrated in FIG. 3, or may be positioned inside the conductor layers.

When the insulating layer includes an electrically-insulating ceramic, the electrode pad, the wiring conductor, and the via conductor may include tungsten (W), molybdenum (Mo), manganese (Mn), silver (Ag), or copper (Cu). The electrode pad, the wiring conductor, and the via conductor may also include an alloy containing one or more of the metals described above.

When the insulating layer includes a resin, the electrode pad, the wiring conductor, and the via conductor may include copper (Cu), gold (Au), aluminum (Al), nickel (Ni), molybdenum (Mo), or titanium (Ti). The electrode pad, wiring conductor, and via conductor may also include an alloy containing one or more of the metals described above.

A plating layer may be provided on an exposed surface of each of the electrode pad, the wiring conductor, and the via conductor, thereby protecting the exposed surfaces of the electrode pad, the wiring, and the via conductor. In the electronic component mounting base 1 with the exposed surfaces being protected, oxidation of the electrode pad, the wiring conductor, or the via conductor hardly occurs.

There may be a plurality of the first via conductors 41 and a plurality of the second via conductors 42, thereby making it possible to reduce self-inductance. The electronic component mounting base 1 with reduced self-inductance exhibits favorable electrical characteristics. When the plurality of first via conductors 41 are present, each of the first via conductors 41 in a plane perspective toward the first surface 211 may be aligned in any first direction in the plane perspective toward the first surface 211. At this time, when a plurality of the second via conductors 42 are present, each of the second via conductors 42 may be aligned in a second direction along the first direction in the plane perspective toward the first surface 211. This may make it easy to control the path of the current. The electronic component mounting base 1, in which the current path is controlled and mutual inductance is reduced, exhibits favorable electrical characteristics. In a plane perspective toward the upper side of the first surface 211, the first via conductors 41 positioned in the first direction and the second via conductors 42 positioned in the second direction are separated from each other.

As for the first via conductors 41, in the plane perspective toward the first surface 211, the center of each first via conductor 41 may be positioned on a virtual straight line A. At this time, as for the second via conductors 42, in the plane perspective toward the first surface 211, the center of each second via conductor 42 may be positioned on a virtual straight line B. When the first via conductors 41 and the second via conductors 42 are positioned on the virtual straight line A and the virtual straight line B. respectively, the virtual straight line A may be parallel to the virtual straight line B. This makes it easier to control the path of the current. The mutual inductance of the electronic component mounting base 1, in which the current path is more easily controlled as described above, is further reduced, and the electrical characteristics of the electronic component mounting base 1 are favorable. The virtual straight line A and the virtual straight line B are depicted by dashed lines in FIG. 2. The virtual straight line A and the virtual straight line B are not required to be strictly parallel to each other, and can be shifted in a range from −1 degree to +1 degree, for example.

If the base 2 has a rectangular shape, the virtual straight line A may be positioned along the first side 23, which is one side of the base 2. The expression that the virtual straight line A extends along the first side 23 may be rephrased as follows: the first via conductors 41 are aligned in a row near the first side 23. The virtual straight line B may be positioned along the second side 24, which is one side of the base 2. The expression that the virtual straight line B extends along the second side 24 may be rephrased as follows: the first via conductors 41 are aligned in a row near the second side 24. Since the virtual straight line A and the virtual straight line B are positioned along the first side 23 and the second side 24, respectively, the first via conductor 41 and the second via conductor 42 may be distanced from each other. Thus, the length of the path along which the current flows may be sufficiently secured, so that the path of the current may be controlled with ease. As a result, the electronic component mounting base 1 with the current path being controlled exhibits favorable electrical characteristics.

In a cross-sectional view orthogonal to the first surface 211 and including the first via conductor 41 and the second via conductor 42, the first conductor layer 61 and the second conductor layer 62 may be connected only by the first via conductor 41. By the first conductor layer 61 and the second conductor layer 62 being connected only by the first via conductor 41, the path of the current flowing through the first conductor layer 61 may be easily controlled. In a cross-sectional view orthogonal to the first surface 211 and including the first via conductor 41 and the second via conductor 42, the second conductor layer 62 and the third conductor layer 63 may be connected only by the second via conductor 42. By the second conductor layer 62 and the third conductor layer 63 being connected only by the second via conductor 42, the path of the current flowing through the second conductor layer 62 may be easily controlled. The mutual inductance of the electronic component mounting base 1, in which the current path is controlled as described above, is further reduced, and the electrical characteristics of the electronic component mounting base 1 are favorable.

In the second insulating layer 22, a third via conductor 43 may be positioned overlapping the first via conductor 41 in the plane perspective toward the first surface 211 and being connected with the second conductor layer 62 and the third conductor layer 63. In other words, the third via conductor 43 extends penetrating through the third surface 221 to the fourth surface 222, connects the second conductor layer 62 and the third conductor layer 63, and is positioned overlapping the first via conductor 41 in the plane perspective toward the first surface 211. The third via conductor 43 may maintain the self-inductance of the electronic component mounting base 1. In addition, the increase in mutual inductance may be reduced and the path of the current may be controlled. The electronic component mounting base 1, in which the self-inductance is secured and the mutual inductance is reduced, exhibits more favorable electrical characteristics.

### Configuration of Electronic Device 100

The electronic device 100 includes the electronic component mounting base 1 and the electronic component 101 mounted on the electronic component mounting base 1.

The electronic component 101 may be, for example, a capacitor, a laser diode (LD), or an optical semiconductor device such as a photo diode (PD). The electronic component 101 may be, for example, an imaging element of a charge coupled device (CCD) type, a complementary metal oxide semiconductor (CMOS) type, or the like. The electronic component 101 may be a light emitting element such as a light emitting diode (LED), an integrated circuit such as a large scale integration (LSI) circuit, or the like. The electronic component 101 may be disposed on the upper surface of the base 2 via an electronic component bonding member 102. As the electronic component bonding member 102, for example, silver epoxy or a thermosetting resin may be used.

The electronic device 100 may include a lid for covering the electronic component 101. When the base 2 constituting the electronic component mounting base 1 includes a frame portion together with a flat plate portion, the lid may be bonded onto the upper surface of the frame portion. The frame portion may be integrated with the lid. When the frame portion and the lid are integrated, the frame portion and the base 2 may be formed of the same material. When the base 2 constituting the electronic component mounting base 1 does not include a frame portion, the electronic device 100 and the lid may be bonded with a lid bonding member. At this time, when the lid bonding member is provided in a thick manner, it is possible to make the lid bonding member function as the frame portion. As the lid bonding member, a thermosetting resin, low-melting point glass, or a brazing material containing a metal component may be used, for example.

When the electronic component 101 is an imaging element of a CMOS, a CCD or the like, or a light emitting element such as an LED, a material having high transparency such as a glass material may be used for the lid. When the electronic component 101 is an integrated circuit or the like, a metal material or an organic material may be used for the lid.

### Manufacturing Method for Electronic Component Mounting Base 1 and Electronic Device 100

Next, an example of a manufacturing method for the electronic component mounting base 1 and the electronic device 100 according to an embodiment of the present disclosure will be described. The example of the manufacturing method indicated below is a manufacturing method for the base 2 using a multi-piece base.

(1) First, ceramic green sheets that configure the base 2 are formed. When obtaining the base 2, which is mainly an aluminum oxide (Al₂O₃) sintered compact, a powder of silica (SiO₂), magnesia (MgO), calcia (CaO), or the like is added as a sintering aid to a powder of Al₂O₃, for example. Subsequently, a suitable binder, solvent, and plasticizer are further added to the Al₂O₃ powder. By kneading after the addition, the mixture is made to be in a slurry state. The ceramic green sheets for the multi-piece base are obtained by performing a molding method such as a doctor blade method or calender roll method on the mixture in the slurry state.

When the base 2 mainly includes a resin, for example, the base 2 is obtained by molding the resin prior to curing through a method such as a transfer mold method or an injection mold method using a metal mold capable of molding the resin in a predetermined shape. The base 2 may be formed by impregnating a base member containing glass fibers with a resin, such as a glass epoxy resin, for example. When the base member containing glass fibers is impregnated with a resin, the base member containing the glass fibers is impregnated with a precursor of epoxy resin. The impregnated base member is thermally cured at a predetermined temperature to obtain the base 2.

(2) Next, a metal paste is applied to or caused to fill portions of the ceramic green sheets, among the ceramic green sheets obtained in the above step (1), that are expected to serve as the electrode pads, the wiring conductors, and the via conductors by using a screen printing method or the like. The metal paste is produced while being adjusted to have an appropriate viscosity by adding a suitable solvent and binder to the metal powder containing the metal material described above and kneading the metal powder with the solvent and binder added. The metal paste may include glass or ceramic in order to increase the bonding strength with the base 2.

When the base 2 includes a resin, the electrode pads, the wiring conductors, and the via conductors are produced by a sputtering method, vapor deposition method, or the like.

(3) Next, the green sheets obtained by the steps (1) and (2) are processed using a metal mold or the like.

(4) Next, the ceramic green sheets to become the insulating layers are layered and pressurized.

(5) Next, the ceramic green sheet layered body is fired at a temperature of approximately 1500° C. to 1800° C. to obtain a multi-piece base in which a plurality of the bases 2 are arranged. In the step (5), the metal paste described above is fired at the same time as the ceramic green sheets to become the base 2 to form the electrode pads, the wiring conductors, and the via conductors. Hereinafter, an object where the electrode pads, the wiring conductors, and the via conductors are fired at the same time in the base 2 is described as the electronic component mounting base 1.

(6) Next, surface treatment such as plating is performed on the surface of the electronic component mounting base 1 obtained in the step (5).

(7) Next, the multi-piece base in which a plurality of the electronic component mounting bases 1 are arranged is divided into pieces. The dividing of the multi-piece base may be performed as follows: dividing grooves are formed in the multi-piece wiring base along the locations to serve as outer edges of the electronic component mounting bases 1, and dividing is carried out along the partitioning grooves. Alternatively, the dividing of the multi-piece base may be performed in such a manner that the cutting is carried out along the locations to serve as the outer edges of the electronic component mounting bases 1 by a slicing method or the like. The dividing grooves may be formed by using a slicing device to form cuts having a depth less than the thickness of the multi-piece base after firing. The dividing grooves may be formed by pressing a cutter blade against the ceramic green sheet layered body for the multi-piece base, by using a slicing device to form cuts having a depth less than the thickness of the ceramic green sheet layered body, or the like. In the above-described multi-piece base, before being divided into pieces, the electrode pads, the pads for external connection, and the exposed wiring conductors may be plated by using electrolysis. Alternatively, in the above-described multi-piece base, after being divided into pieces, the electrode pads, the pads for external connection, and the exposed wiring conductors may be plated by using electrolysis.

(8) Next, the electronic component 101 is mounted on the upper surface or the lower surface of the electronic component mounting base 1. The electronic component 101 may be electrically bonded to the electronic component mounting base 1 by the electronic component bonding member 102, for example, wire bonding. At this time, the electronic component 101 may be fixed to the electronic component mounting base 1 by providing an adhesive or the like on the electronic component 101 or the electronic component mounting base 1. The electronic component mounting base 1 and the lid may be bonded using a lid bonding member after the electronic component 101 has been mounted in the mounting region 60 of the electronic component mounting base 1.

The electronic component mounting base 1 may be produced as in the steps (1) to (7) described above. Then, as in the step (8), the electronic component 101 may be mounted on the electronic component mounting base 1 having been obtained by the steps (1) to (7), so as to produce the electronic device 100. Note that the order of the above-described steps (1) to (8), the number of steps, and the like are not specified.

Note that the present disclosure is not limited to the examples in the embodiments described above. Further, various modifications of numerical values and the like are possible in each of the configurations. For example, the arrangement, number, and shape of the electrode pads, the wiring conductors, the via conductors and the insulating layers, the mounting method for the electronic component 101, and the like in the embodiments of the present disclosure are not specified within a range in which no constitutive inconsistency occurs. Various combinations of the embodiments of the present disclosure are not limited to the examples in the above-described embodiments.

### REFERENCE SIGNS LIST

1 Electronic component mounting base
2 Base
21 First insulating layer
211 First surface
212 Second surface
22 Second insulating layer
221 Third surface
222 Fourth surface
23 First side
24 Second side
41 First via conductor
42 Second via conductor
43 Third via conductor
60 Mounting region
61 First conductor layer
62 Second conductor layer
63 Third conductor layer
71 First electrode portion
72 Second electrode portion
80 Mounting substrate
100 Electronic device
101 Electronic component
102 Electronic component bonding member

1. An electronic component mounting base, comprising:
a base comprising a first insulating layer provided with a first surface and a second surface positioned opposite to the first surface, and a second insulating layer provided with a third surface facing and overlapping the second surface and a fourth surface positioned opposite to the third surface;
a first conductor layer comprising a first electrode portion and positioned on the first surface;
a second conductor layer positioned between the second surface and the third surface;
a third conductor layer comprising a second electrode portion and positioned on the fourth surface;
a first via conductor that extends penetrating from the first surface to the second surface, and connects the first conductor layer and the second conductor layer; and
a second via conductor that extends penetrating from the third surface to the fourth surface, and connects the second conductor layer and the third conductor layer,
wherein a distance D1 between the first electrode portion and the first via conductor is longer than a distance D2 between the first electrode portion and the second via conductor in a plane perspective toward the first surface, and a distance D3 between the second electrode portion and the second via conductor is longer than a distance D4 between the second electrode portion and the first via conductor in the plane perspective.

2. The electronic component mounting base according to claim 1,
wherein the first electrode portion, the first via conductor, the second electrode portion, and the second via conductor are disposed on a virtual straight line X in the plane perspective.

3. The electronic component mounting base according to claim 1, further comprising:
a plurality of the first via conductors and a plurality of the second via conductors.

4. The electronic component mounting base according to claim 1,
wherein the first conductor layer and the second conductor layer are connected only by the first via conductor.

5. The electronic component mounting base according to claim 1, further comprising:
a third via conductor that extends penetrating from the third surface to the fourth surface, connects the second conductor layer and the third conductor layer, and is positioned overlapping the first via conductor in the plane perspective.

6. The electronic component mounting base according to claim 1,
wherein the second conductor layer and the third conductor layer are connected only by the second via conductor.

7. The electronic component mounting base according to claim 3,
wherein the plurality of first via conductors are aligned in a first direction in the plane perspective, and
the plurality of second via conductors are separated from the plurality of first via conductors and aligned in a second direction along the first direction in the plane perspective.

8. The electronic component mounting base according to claim 7,
wherein the plurality of first via conductors are provided in such a manner that a center of each of the first via conductors is positioned along a virtual straight line A in the plane perspective,
the plurality of second via conductors are provided in such a manner that a center of each of the second via conductors is positioned along a virtual straight line B in the plane perspective, and
the virtual straight line A and the virtual straight line B are parallel to each other.

9. The electronic component mounting base according to claim 8,
wherein the base has a rectangular shape comprising a first side and a second side facing the first side in a plan view toward the first surface,
the virtual straight line A is set along the first side, and
the virtual straight line B is set along the second side.

10. An electronic device comprising:
the electronic component mounting base according to claim 1; and
an electronic component connected to the electronic component mounting base.

11. The electronic component mounting base according to claim 1,
wherein at least a part of the second via conductor is positioned on an extension line in the vertical direction of the first electrode portion in a cross-sectional view.

12. The electronic component mounting base according to claim 1,
wherein at least a part of the first via conductor is positioned on an extension line in the vertical direction of the second electrode portion in a cross-sectional view.

13. The electronic component mounting base according to claim 1,
wherein the first conductor layer extends over the entire surface of the first surface.

14. The electronic component mounting base according to claim 1,
wherein the second conductor layer extends over the entire surface between the second and third surfaces.

15. The electronic component mounting base according to claim 1,
wherein the third conductor layer extends over the entire surface of the fourth surface.
